(19) United States
(12) Patent Application Publication
(10) Pub. No.: US 2011/0285438 A1
(43) Pub. Date: Nov. 24, 2011

(54) PLL CIRCUIT FOR REDUCING REFERENCE LEAK AND PHASE NOISE

(76) Inventors: Norihide Kinugasa, Kyoto (JP); Koji Chiba, Kyoto (JP)

(21) Appl. No.: 13/114,569

(22) Filed: May 24, 2011

(30) Foreign Application Priority Data
May 24, 2010 (JP) 2010-118010
Jan. 25, 2011 (JP) 2011-012793

(51) Int. Cl. H03L 7/06

(52) U.S. Cl. 327/157

(57) ABSTRACT

A phase locked loop circuit comprises a charge pump fed with a phase error output signal; a loop filter charged or discharged with an output of the charge pump; an oscillator, an oscillating frequency of which is controlled by a voltage of the loop filter; and a frequency/phase comparator having a switching function which is fed with a reference signal and an output signal of the oscillator and outputs the phase error output signal; the frequency/phase comparator being configured to, based on a lock detection signal, switch between comparing frequencies by detecting rising edges of the reference signal and the comparison signal to detect a phase difference between the reference signal and the comparison signal, and comparing phases by detecting voltage levels of the reference signal and the comparison signal to detect a phase difference between the reference signal and the comparison signal.

The disclosure of Japanese Patent Application No. 2010-118010 filed on May 24, 2010 and No. 2011-12793 filed on Jan. 25, 2011 including specification, drawings and claims are incorporated herein by reference in its entirety.

### BACKGROUND OF THE INVENTION

1. Field of the Invention

The present invention relates to a clock generating circuit such as a PLL (phase locked loop) circuit. Particularly, the present invention relates to a technique for controlling a frequency/phase comparator according to an operational state of the PLL circuit.

2. Description of the Related Art

FIG. 16 shows a frequency/phase comparator 300 which is a constituent in the conventional PLL circuit disclosed in Japanese Laid-Open Patent Application Publication No. Hei. 11-234123.

Referring to FIG. 16, a reference signal FREF and a comparison signal FVCO are input to input terminals 10 and 20, respectively, and are input to an edge comparator 50 through inverters 1 and 2, respectively. The edge comparator 50 compares the reference signal FREF and the comparison signal FVCO and outputs phase error output signals (UP signal and DN signal) according to a result of the comparison to the corresponding output signal terminals 30 and 40, respectively.

Japanese Laid-Open Patent Application Publication No. Hei. 11-234123 discloses that the frequency/phase comparator of FIG. 16 is operated to output the UP signal and the DN signal such that they are at Low level for the same period of time and at the same time, thereby eliminating a cause of a reference leak or a cause of an increase in a phase noise.

Japanese Laid-Open Patent Application Publication No. Hei. 8-307254 discloses that in a synchronous clock generating circuit, a current value of a charge pump is switched based on a lock detection signal to eliminate a cause of a reference leak or a cause of an increase in a phase noise, after a lock state is formed.

Japanese Laid-Open Patent Application Publication No. 2000-165235 discloses that, in a phase comparator and a charge pump circuit, a phase error signal is fed to a delay circuit, and an output time of the charge pump circuit is increased if a phase difference is large, while the output time of the charge pump circuit is decreased to a level at which a phase noise is not worsened if the phase difference is small, thereby reducing a phase noise after a lock state is formed.

Japanese Laid-Open Patent Application Publication No. 2000-323985 discloses a charge pump circuit including a current compensation circuit for suppressing a fluctuation in a charge pump current depending on a fluctuation in an output voltage value of a charge pump, thereby preventing a reference noise from getting worse due to a mismatch of the charge pump current.

Japanese Laid-Open Patent Application Publication No. 2007-295165 discloses a charge pump circuit including a delay unit of a phase error output signal to reduce a dead band, thereby eliminating a cause of a reference leak or a cause of an increase in a phase noise, like the PLL circuit disclosed in Japanese Laid-Open Patent Application Publication No. Hei. 11-234123.

In each of the PLL circuits disclosed in Japanese Laid-Open Patent Application Publication Nos. Hei. 11-234123, 2000-323985, and 2007-295165, the frequency/phase comparator is used.

It is clear in each of the PLL circuits disclosed in Japanese Laid-Open Patent Application Publication Nos. Hei. 8-307254 and 2000-165235, a constituent named a phase comparator refers to a frequency/phase comparator rather than a phase comparator itself performing its original function, from recitation of a loop filter and a frequency synthesizer.

Japanese Laid-Open Patent Application Publication No. 2001-196925 discloses that the frequency comparator and the phase comparator are individually used to configure the PLL circuit. It discloses a circuit configuration of the frequency comparator but does not mention an operational waveform of a phase error output of the phase comparator, or switching between an operation of the frequency comparator and an operation of the phase comparator. In other words, it merely discloses that a feedback loop basically has two loops, i.e., a loop for for comparing frequencies and a loop for comparing phases and the frequency comparator in these loops is operative stably.

Japanese Laid-Open Patent Application Publication No. 2000-134091 discloses that only charging and discharging required to compensate an original phase difference between the reference signal and the comparison signal is performed by the charge pump to stabilize an operation. This configuration has a drawback that, it is necessary to set a delay amount to a dead band or less, and a charging current and a discharging current are not generated as an error output, in a state where there is a match between the phases to be compared and the comparison signal is locked to the reference signal, thereby causing a dead band.

### SUMMARY OF THE INVENTION

As described above, the frequency/phase comparator of FIG. 16, which is a conventional example, is adapted to output the UP signal and the DN signal at the same time because of the operation of the delay unit 3, to prevent the dead band from being generated. FIGS. 17A to 17C show output waveforms of the UP signal 30 and the DN signal 40 of FIG. 16. FIG. 17A shows a case where a phase of the comparison signal FVCO20 is retarded with respect to a reference phase (rising timing) of the reference signal FREF10 (phase lag). FIG. 17B shows a case where the phase of the comparison signal FVCO20 is advanced with respect to the reference phase (rising timing) of the reference signal FREF10 (phase lead). FIG. 17C shows a case where there is a match between the phase of the comparison signal FVCO20 and the reference phase (rising timing) of the reference signal FREF10 (phase match). As can be seen from FIGS. 17A to 17C, the UP signal 30 and the DN signal 40 are output at the same time during a period of a delay amount (D) generated by the delay element 3, regardless of whether a phase difference of the phase lag or the phase lead is small.

FIG. 18 depicts how the UP signal 30 corresponding to an output period of UP current and the DN signal 40 corresponding to an output period of DN current change with respect to the phase difference. As shown in FIG. 18, irrespective of a magnitude of the phase difference, the UP signal 30 and the DN signal 40 are always output according to the delay amount (D) generated by the delay element 3. The delay amount (D) generated by the delay element 3 is set to a value (x+δ) which is a little larger than a dead band (x).

As the delay amount (D) is set larger, a period of time for which the UP current 30 and the DN current 40 are output at the same time increases. Therefore, if there is a difference between a charging current (FIG. 17A) and a discharging current (FIG. 17B) in the charge pump current, during the period of time for which the UP signal 30 and the DN signal 40 are output at the same time, a steady phase error occurs to compensate the difference, and the UP current 30 or the DN current 40 flowing during the resulting phase error period causes a fluctuation in a voltage of a loop filter.

As a consequence, in the configurations disclosed in the above illustrated publications, a spurious (reference leak) results in the frequencies with which the phases are compared. The aforesaid difference between the charging current and the discharging current is also attributed to a change in an output resistance of a current source constituting a charge pump output depending on a magnitude of the voltage of the loop filter.

The above spurious brings about a phenomenon that a jitter increases in a lock state between the comparison signal and the reference signal, and therefore, must be minimized. However, in addition to the above stated reason, it is necessary to set the delay amount of the delay element 3 so that the period of time for which the UP signal 30 and the DN signal 40 are output at the same time reaches a duration which is not less than the dead band. Therefore, the period of time for which the difference between the UP signal 30 and the DN signal 40 is generated cannot be reduced.

Furthermore, the conventional frequency comparator circuit includes many elements, which would cause a thermal noise.

The present invention has been developed under the circumstances, and an object of the present invention is to provide a PLL circuit capable of reducing a reference leak and suppressing a phase noise.

A phase locked loop circuit of the present invention comprises a charge pump fed with a phase error output signal; a loop filter charged or discharged with an output of the charge pump; an oscillator, an oscillating frequency of which is controlled in accordance with a voltage of the loop filter; and a frequency/phase comparator having a switching function which is fed with a reference signal and an output signal of the oscillator and outputs the phase error output signal between the reference signal and a comparison signal based on the output signal of the oscillator; the frequency/phase comparator having a switching function being configured to, based on a lock detection signal input to the frequency/phase comparator, switch between comparing frequencies of the reference signal and the comparison signal by detecting rising edges of the reference signal and the comparison signal to detect a phase difference between the reference signal and the comparison signal, and comparing phases of the reference signal and the comparison signal by detecting voltage levels of the reference signal and the comparison signal to detect a phase difference between the reference signal and the comparison signal.

The frequency/phase comparator having a switching function may include a frequency comparator circuit for comparing the frequencies of the reference signal and the comparison signal; a phase comparator circuit for comparing the phases of the reference signal and the comparison signal; a switching unit configured to, based on the lock detection signal, switch an operation of the frequency/phase comparator having a switching function to cause the frequency comparator circuit to compare the frequencies or the phase comparator circuit to compare the phases; and a comparison period signal input terminal fed with a signal (comparison period signal) indicating a comparison period during which the phase comparator circuit is activated to compare the phases; wherein the phase comparator circuit may compare the phases in a state where the comparison period signal is at a predetermined voltage level.

The frequency/phase comparator having a switching function may include a frequency comparator circuit for comparing the frequencies of the reference signal and the comparison signal; a reset signal input terminal through which a reset signal is input to the frequency comparator circuit; and a reset state releasing unit configured to limit the frequency comparator circuit such that the reset state is released, when the reference signal and the comparison signal reach a predetermined voltage level after the reset signal is input to the frequency comparator circuit in the reset state where the phase error output signal is not output.

The phase locked loop circuit may further comprise a frequency divider for dividing a frequency of the output signal of the oscillator; wherein a phase difference between the reference signal and an output signal of the frequency divider may be the phase error output signal.

The frequency/phase comparator having a switching function may include a lock detection signal generating unit fed with the comparison period signal and the reference signal and configured to generate the lock detection signal based on the comparison period signal and the reference signal.

The frequency/phase comparator having a switching function may limit the comparison period during which the phase comparator circuit outputs the phase error output signal in accordance with the comparison period signal input to the phase comparator circuit.

The phase comparator circuit in the frequency/phase comparator having a switching function may detect and output a voltage level of the reference signal and a voltage level of the comparison signal, as the phase error output signal.

The phase comparator circuit may include a phase comparison output signal generating circuit which outputs, in the comparison period, an UP signal indicating that a phase of the comparison signal is retarded with respect to a phase of the reference signal during a period for which a voltage level of the reference signal is a predetermined voltage level and a voltage level of a first delay signal generated by delaying an inverted signal of the comparison signal by a predetermined delay time is a predetermined voltage level, and which outputs, in the comparison period, a DN signal indicating that the phase of the comparison signal is advanced with respect to the phase of the reference signal during a period for which a voltage level of the comparison signal and a voltage level of a second delay signal generated by retarding an inverted signal of the reference signal by a predetermined delay time are a predetermined voltage level.

The comparison period signal may be a signal that transitions in voltage level to a second voltage level higher than a first voltage level in the comparison period including a time when the comparison signal switches in voltage level from the first voltage level to the second voltage level; wherein the phase comparison output signal generating circuit may include: a first inverter for inverting the comparison signal; a first delay unit for delaying the comparison signal by a predetermined delay time; a first NAND circuit fed with the first delay signal, the reference signal and the comparison period signal; a second inverter for inverting the reference signal; a second delay unit for delaying the reference signal by a predetermined delay time; and a second NAND circuit fed with the second delay signal, the comparison signal and the comparison period signal.

The lock detection signal generating unit may generate the lock detection signal when it is detected that the reference signal switches to a predetermined voltage level a predetermined number of times within the comparison period based on the comparison period signal.

In accordance with the PLL circuit of the present invention, if it is detected that the phase difference between the reference signal and the comparison signal is small and they are close to the lock state, based on the lock direction signal, the frequency/phase comparator having a switching function does not compare the frequencies of the reference signal and the comparison signal but compares the phases of the reference signal and the comparison signal, and outputs the phase error signal, while if it is detected that the phase difference is large, based on the lock direction signal, the frequency/phase comparator having a switching function compares the frequencies and outputs the phase error signal.

In the frequency/phase comparator having a switching function for performing switching control using the lock detection signal, if it is detected that the phase difference is relatively large based on the lock detection signal, the frequency comparator circuit outputs the phase error output signal, and thus it is possible to shorten a time required to reach the lock state in which the comparison signal is locked to the reference signal. On the other hand, if it is detected that the comparison signal and the reference signal are close to the lock state, based on the lock detection signal, the phase comparator circuit which is less likely to generate a reference leak outputs the phase error output signal, and therefore, it is possible to suppress a reference leak due to a mismatch between the charge pump currents, and lessen a spurious and a noise amount.

Since the phase comparator circuit is constituted by fewer elements and constituents, it is possible to suppress a thermal noise.

In accordance with the phase locked loop circuit of the present invention, since the phase comparator circuit compares a voltage level of the comparison signal to a voltage level of the reference signal in a state where they are close to a lock state, and the phase error output signal is fed from the phase comparator circuit to the charge pump and then fed-back to a voltage controlled oscillator (VCO) via a loop filter, it is possible to prevent a sudden phase error signal from being output unexpectedly due to a disturbance to the reference signal. As a result, the phase locked circuit can continue a stable operation

In accordance with the phase locked loop circuit of the present invention, since the operation of the frequency/phase comparator is limited so that the reset state is released during a period of time for which both of the two signals input to the frequency comparator circuit are at a predetermined voltage level, it is possible to prevent a wrong phase error signal from being output when a frequency draw-in operation is initiated. This makes it possible to shorten a lock time required after a power supply is ON or a reset state is released.

As should be appreciated from the above, it is possible to shorten a lock time required after a power supply is ON or a reset state is released, and to reduce a spurious caused by a reference leak or a jitter in a lock state where the comparison signal is locked to the reference signal.

The above and further objects, features and advantages of the present invention will more fully be apparent from the following detailed description of preferred embodiments with accompanying drawings.

### BRIEF DESCRIPTION OF THE DRAWINGS

FIG. 1 is a view showing an exemplary configuration of a PLL circuit according to Embodiment 1 of the present invention.

FIG. 2 is a view showing an exemplary configuration of a PLL circuit according to Embodiment 2 of the present invention.

FIG. 3 is a view showing an exemplary configuration of a PLL circuit according to Embodiment 3 of the present invention.

FIG. 4 is a view showing an internal configuration of a frequency/phase comparator having a switching function in the PLL circuit of FIG. 1.

FIG. 5 is a view showing an internal configuration of a frequency/phase comparator having a switching function in the PLL circuit of FIG. 2.

FIG. 6 is a view showing an internal configuration of a frequency/phase comparator having a switching function in the PLL circuit of FIG. 3.

FIG. 7 is a view showing an internal configuration of a phase comparator circuit in the frequency/phase comparator having a switching function of FIG. 4.

FIG. 8 is a view showing a phase relationship between a comparison signal and a comparison period signal which are input to the phase comparator circuit of FIG. 7.

FIGS. 9A to 9C are views showing output waveforms of signals of the phase comparator circuit of FIG. 7.

FIGS. 10A to 10C are views showing output waveforms of signals of the phase comparator circuit of FIG. 7.

FIGS. 11A to 11C are views showing output waveforms of signals in a case where a phase lag occurs and its phase difference is small in the phase comparator circuit of FIG. 7.

FIGS. 12A to 12C are views showing output waveforms of signals in a case where a phase lead occurs and its phase difference is small in the phase comparator circuit of FIG. 7.

FIG. 13 is a view showing a relationship between a phase difference between a reference signal and a comparison signal in the phase comparator circuit of FIG. 7, and an output period of a charge pump current (UP current) based on UP signal and an output period of a charge pump current (DN current) based on DN signal.

FIG. 14 is a view showing an internal configuration of the frequency comparator circuit of FIG. 5.

FIG. 15 is a view showing output waveforms of the UP signal and DN signal in the frequency comparator circuit of FIG. 14, just after a power supply is ON.

FIG. 16 is a circuit diagram showing a configuration of a conventional frequency comparator circuit.

FIGS. 17A to 17C are views showing output waveforms after a reset state is released in a conventional frequency comparator circuit.

FIG. 18 is a view showing a relationship between a phase difference and a phase error current in a conventional frequency comparator circuit.

FIG. 19 is a view showing output waveforms after a reset state is released in a conventional frequency comparator circuit.

### DETAILED DESCRIPTION OF THE PREFERRED EMBODIMENTS

Hereinafter, preferred embodiments of the present invention will be described with reference to the drawings. Throughout the drawings, the same or corresponding constituents and components are designated by the same reference symbols and will not be described repetitively in some cases.

### Embodiment 1

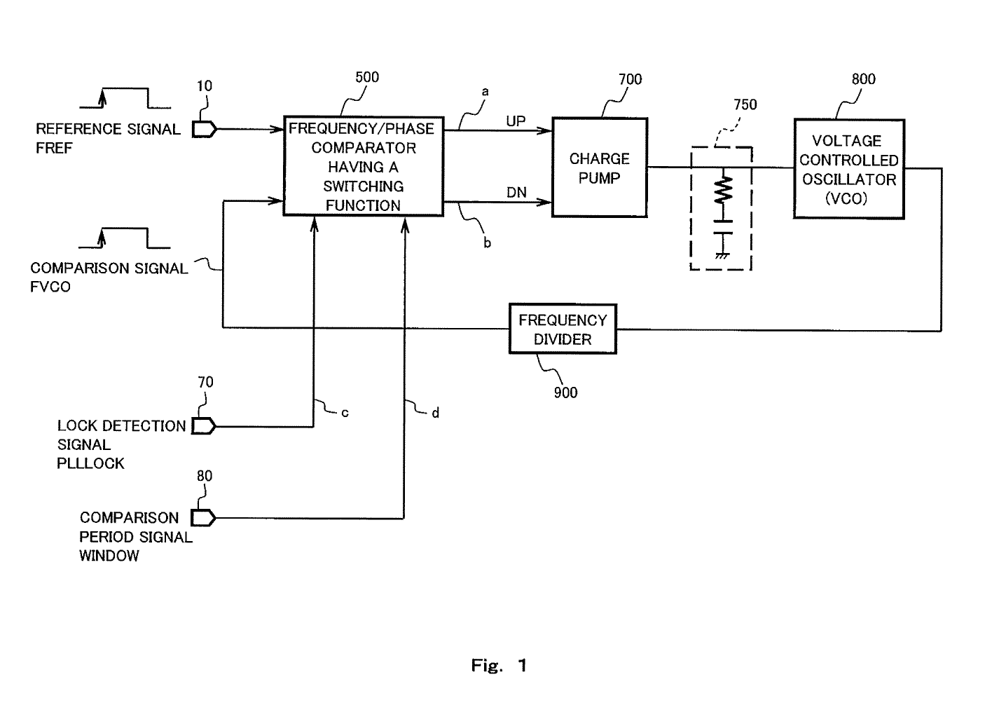

FIG. 1 shows a configuration of a PLL circuit according to Embodiment 1 of the present invention. The PLL circuit includes a frequency/phase comparator 500 having a switching function (hereinafter simply referred to as frequency/phase comparator 500), a charge pump 700, a loop filter 750, a voltage controlled oscillator (VCO) 800 and a frequency divider 900 for dividing a frequency of an output of the VCO 800.

An oscillating frequency of the VCO 800 is controlled in accordance with a voltage of the loop filter 750. A capacitor in the loop filter 750 is charged or discharged by an output current of the charge pump 700, and a voltage of the capacitor changes according to the charging or discharging. The charge pump 700 is fed with phase error output signals (UP signal and DN signal) output from the frequency/phase comparator 500, and outputs a current according to the phase error output signals. The frequency/phase comparator 500 is fed with a reference signal FREF10 and a comparison signal FVCO which is a frequency-divided signal generated by dividing a frequency of an output signal of the VCO800 by the frequency divider 900, and compares a phase of the reference signal FREF10 and a phase of the comparison signal FVCO. The frequency/phase comparator 500 is configured to switch between comparing frequencies of the reference signal FREF10 and the comparison signal FVCO by detecting rising edges of the two signals to detect a phase difference between these two signals and comparing phases of the two signals by detecting voltage levels of the two signals to detect a phase difference between the two signals, in accordance with a lock detection signal PLLLOCK70 input to the frequency/phase comparator 500 as a function switching signal.

The frequency/phase comparator 500 is further fed with a comparison period signal WINDOW80 indicating a period (comparison period) for which a phase comparison circuit (described later) is activated to compare phases of the reference signal FREF10 and the comparison signal FVCO.

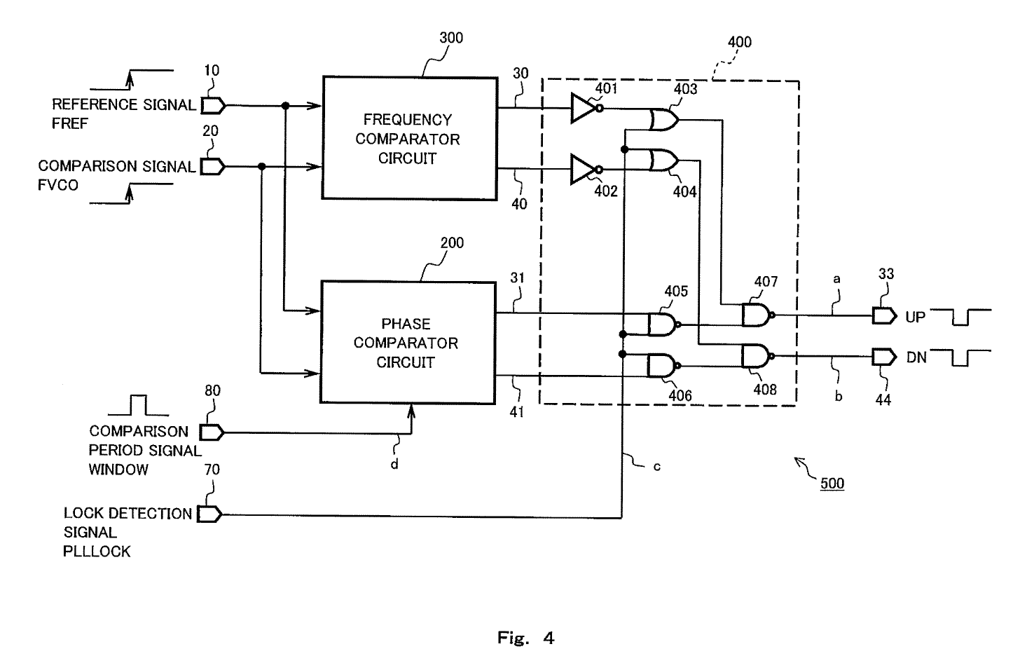

FIG. 4 is a view showing an internal configuration of the frequency/phase comparator 500 in the PLL circuit of FIG. 1. The frequency/phase comparator 500 includes a frequency comparator circuit 300 for comparing the frequencies and a phase comparator circuit 200 for comparing the phases. The frequency comparator circuit 300 and the phase comparator circuit 200 are each fed with the reference signal FREF10 and the comparison signal FVCO20. The phase comparator circuit 200 is also fed with the comparison period signal WINDOW80. The frequency comparator circuit 300 outputs UP signal 30 and DN signal 40 which are phase error output signals based on a phase difference between the reference signal FREF10 and the comparison signal FVCO20. The phase comparator circuit 200 outputs UP signal 31 and DN signal 41 which are phase error output signals based on a phase difference between the reference signal FREF10 and the comparison signal FVCO20. The frequency/phase comparator 500 includes a switching unit 400 for switching of an operation of the frequency/phase comparator 500 based on the lock detection signal PLLLOCK70 so that the frequency comparator circuit 300 compares the frequencies of the reference signal FREF10 and the comparison signal FVCO20 or the phase comparator circuit 200 compares the phases of the reference signal FREF10 and the comparison signal FVCO20. Based on the lock detection signal PLLLOCK70, the switching unit 400 performs switching to output either the UP signal 30 and the DN signal 40 which are the output signals of the frequency comparator circuit 300 or the UP signal 31 and the DN signal 41 which are the output signals of the phase comparator circuit 200.

The frequency comparator circuit 300 includes a frequency/phase comparator circuit capable of comparing the phases as well as the frequencies. In this embodiment, it is supposed that even when the frequency/phase comparator circuit is used as the frequency comparator circuit 300, the frequency/phase comparator circuit is configured to compare only the frequencies.

To be specific, the switching unit 400 includes inverters 401 and 402 for inverting the UP signal 30 and the DN signal 40 output from the frequency comparator circuit 300, respectively, an OR circuit 403 fed with an output signal of the inverter 401 and the lock detection signal PLLLOCK70, an OR circuit 404 fed with an output signal of the inverter 402 and the lock detection signal PLLLOCK70, a NAND circuit 405 fed with the UP signal 31 output from the phase comparator circuit 200 and the lock detection signal PLLLOCK70, a NAND circuit 406 fed with the DN signal 41 output from the phase comparator circuit 200 and the lock detection signal PLLLOCK70, a NAND circuit 407 fed with an output signal of the OR circuit 403 and an output signal of the NAND circuit 405 and outputs UP signal 33, and a NAND circuit 408 fed with an output signal of the OR circuit 404 and an output signal of the NAND circuit 406 and outputs a DN signal 44. In this configuration, when a voltage level of the lock detection signal PLLLOCK70 is a first voltage level Lo (lock state between the reference signal FREF10 and the comparison signal FVCO20 is not detected), the output signal of the NAND circuit 405 and the output signal of the NAND circuit 406 are maintained at second voltage level Hi regardless of the UP signal 31 and the DN signal 41 of the phase comparator circuit 200, and as a result, the switching unit 400 outputs the UP signal 30 and the DN signal 40 output from the frequency comparator circuit 300, through output terminals 33 and 34, respectively, regardless of the UP signal 31 and the DN signal 41 of the phase comparator circuit 200. When the voltage level of the lock detection signal PLLLOCK70 rises from the first voltage level Lo to the second voltage level Hi (lock state between the reference signal FREF10 and the comparison signal FVCO20 is detected), the output signal of the OR circuit 403 and the output signal of the OR circuit 404 are maintained at second voltage level Hi regardless of the UP signal 30 and the DN signal 40 of the frequency comparator circuit 300, and as a result, the switching unit 400 outputs the UP signal 31 and the DN signal 41 output from the phase comparator circuit 200, through the output terminals 33 and 34, respectively.

In the manner as described above, the frequency/phase comparator 500 outputs the UP signal and the DN signal through the output terminals 33 and 44, respectively, in accordance with the lock detection signal PLLLOCK70.

The switching operation will now be described in detail. During a period for which the lock detection signal PLLLOCK70 is at the first voltage level Lo, PLL is in a transient response state, and therefore, the phase error is detected effectively by comparing the frequencies. Therefore, the frequency/phase comparator 500 outputs the UP signal 30 and DN signal 40 which are the output signals of the frequency comparator circuit 300, as effective signals, through the output terminals 33 and 44, respectively.

When the PLL is close to the lock state, the lock detection signal PLLLOCK70 transitions from the first voltage level Lo to the second voltage level Hi higher than the first voltage level Lo. In response to this, the frequency/phase comparator 500 disconnects the frequency comparator circuit 300 for comparing the frequencies from the 500, and outputs the UP signal 31 and DN signal 41 which are the output signals of the phase comparator circuit 200, as effective signals, through the output terminals 33 and 44, respectively. The lock detection signal PLLLOCK70 is generated (transitions from the first voltage level Lo to the second voltage level Hi) when it is detected that the reference signal FREF10 switches to a predetermined voltage level (Hi) a predetermined number of times (N times) continuously, during a comparison period for which the comparison period signal WINDOW80 is at the predetermined voltage level (Hi).

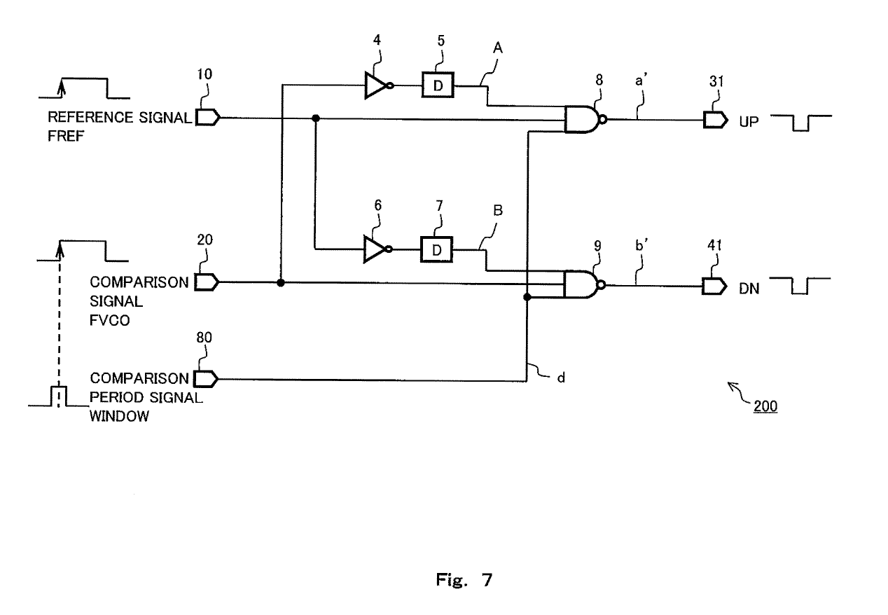

FIG. 7 is a view showing an internal configuration of the phase comparator circuit 200 in the frequency/phase comparator 500 of FIG. 4. The phase comparator circuit 200 is configured to compare the phases of the reference signal FREF10 and the comparison signal FVCO20 in the comparison period for which the comparison period signal WINDOW80 is at the predetermined voltage level (Hi). To be specific, the phase comparator circuit 200 includes a phase comparison output signal generating circuit which outputs, in the comparison period, the UP signal 31 indicating that the phase of the comparison signal FVCO20 is retarded with respect to the phase of the reference signal FREF10 during a period for which a voltage level of the reference signal FREF10 is a predetermined voltage level and a voltage level of a first delay signal A generated by delaying an inverted signal of the comparison signal FVCO20 by a predetermined delay time is a predetermined voltage level, and which outputs, in the comparison period, the DN signal 41 indicating that the phase of the comparison signal FVCO20 is advanced with respect to the phase of the reference signal FREF10 during a period for which a voltage level of the comparison signal FVCO20 is a predetermined voltage level and a voltage level of a second delay signal B generated by retarding an inverted signal of the reference signal FREF10 by a predetermined delay time is a predetermined voltage level. To be more specific, the phase comparison output signal generating circuit includes a first inverter 4 for inverting the comparison signal FVCO20, a first delay unit 5 for delaying the inverted signal of the comparison signal FVCO20 by a predetermined delay time, a first NAND circuit 8 fed with the first delay signal A, the reference signal FREF10 and the comparison period signal WINDOW80, a second inverter 6 for inverting the reference signal FREF10, a second delay unit 7 for delaying the inverted signal of the reference signal FREF10 by a predetermined delay time, and a second NAND circuit 9 fed with the second delay signal B, the comparison signal FVCO20, and the comparison period signal WINDOW80. The delay time of the first delay unit 5 may be different from the delay time of the second delay unit 7 to compensate a difference between a time when the UP signal 31 is input to the charge pump 700 and a time when the DN signal 41 is input to the charge pump 700, in a case where the difference exists. Or, the delay time of the first delay unit 5 may be equal to the delay time of the second delay unit 7 in a case where there is no time difference.

Since the voltage level of the reference signal FREFF 10 is compared to the voltage level of the comparison signal FVCO20, in the phase comparator circuit 200 configured as described above, their logics are calculated and a phase difference between the two signals is detected. AND operation of the reference signal FREF10 and an inverted signal of the comparison signal FVCO20 allows detection of a phase lag of the comparison signal FVCO20, while AND operation of an inverted signal of the reference signal FREF10 and the comparison signal FVCO20 allows detection of a phase lead of the comparison signal FVCO20.

The comparison period signal WINDOW80 limits a timing at which the reference signal FREFF10 is compared to the comparison signal FVCO20 to their rising edges and nullifies phase error detection at their falling edges. The phase error signals output from the phase comparator circuit 200 are three-phase outputs in which only the UP signal 31 is a pulse output, only the DN signal 41 is a pulse signal, and both of the UP signal 31 and the DN signal 41 are pulse outputs.

During a period for which the comparison period signal WINDOW80 is at the first voltage level Lo, the UP signal 31 and the DN signal 41 are not output as pulses. Therefore, the charge pump 700 generates no current and the loop filter 750 holds a voltage.

In the phase comparator circuit 200, a problem that a lock state is released by falsely detecting edges associated with a noise will not arise, and therefore, a stable lock state can continue, unlike edge detection using a latch (a frequency/phase comparator circuit 50 which compares frequencies and compares phases (as described later)).

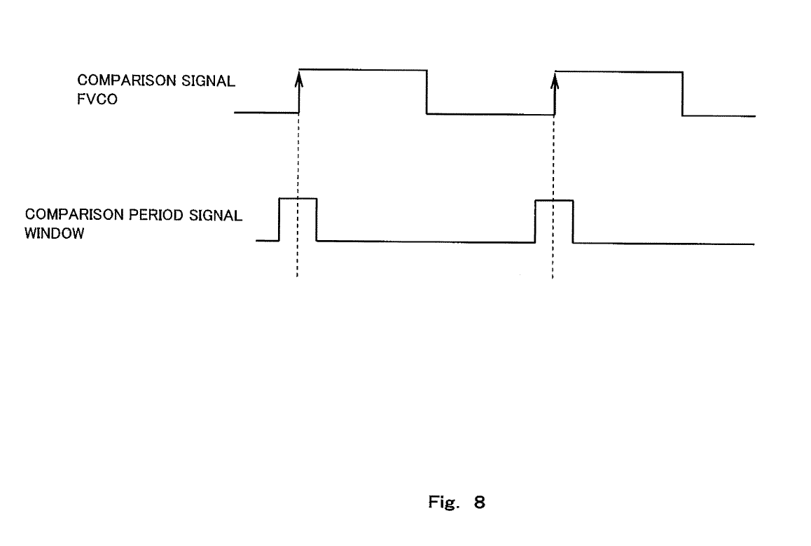

FIG. 8 is a view showing a phase relationship between the comparison signal FVCO20 and the comparison period signal WINDOW80 which are input to the phase comparator circuit 200 of FIG. 7.

The comparison period signal WINDOW80 to be input to the phase comparator circuit 200 is set to a signal which is at second voltage level Hi higher than the first voltage level Lo during a comparison period including a time at which the voltage level of the comparison signal FVCO20 switches from the first voltage level Lo to the second voltage level Hi higher than the first voltage level Lo (i.e., rising edge). In other words, the comparison period signal WINDOW80 is set to a signal generated as having a predetermined duration before and after a time of a comparison timing edge (rising edge) of the comparison signal FVCO20.

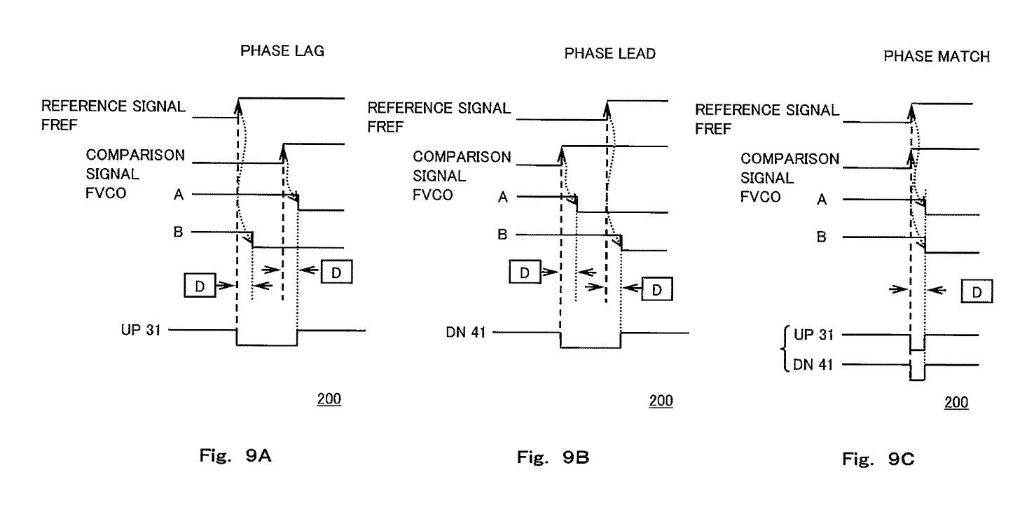

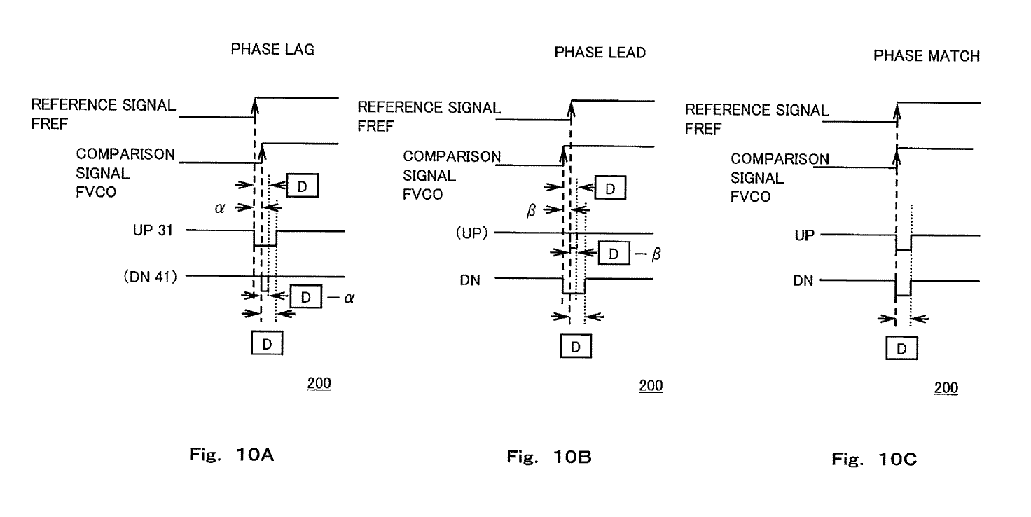

FIGS. 9A to 9C, and FIGS. 10A to 10C are views showing output waveforms of signals of the phase comparator circuit 200 of FIG. 7. FIGS. 9A and 10A are waveform diagrams showing a state of a phase lag in which the comparison signal FVCO20 rises after the reference signal FREF10 rises, and FIGS. 9B and 10B are waveform diagrams showing a state of a phase lead in which the comparison signal FVCO20 rises before the reference signal FREF10 rises. FIGS. 9C and 10C are waveform diagrams showing a state where the comparison signal FVCO20 and the reference signal FREF10 rise simultaneously. FIGS. 9A to 9C are waveform diagrams showing a state where a phase difference between the reference signal FREF10 and the comparison signal FVCO20 is relatively large (phase difference α or β is larger than a delay period D), while FIGS. 10A to 10C are waveform diagrams showing a state where a phase difference between the reference signal FREF10 and the comparison signal FVCO20 is relatively small (phase difference α or β is not larger than the delay period D). Since the comparison period signal WINDOW80 of FIG. 8 is input so that a phase error between rising edges of the reference signal FREF10 and the comparison signal FVCO20 is UP signal 31 and DN signal 41, output waveforms near the rising edges are shown in the example of FIGS. 9A to 9C.

As described above, an internal signal A depicted in FIGS. 9A to 9C is the first delay signal generated by inverting the comparison signal FVCO20 by the first inverter 4 and by delaying the inverted signal by the first delay unit 5, in the phase comparator circuit 200 of FIG. 7, while an internal signal B of FIGS. 9A to 9C is the second delay signal generated by inverting the reference signal FREF10 by the second inverter 6 and by delaying the inverted signal by the second delay unit 7, in the phase comparator circuit 200 of FIG. 7. As shown in FIGS. 9A and 10A, in the case of the phase lag, an overlapping period of Hi level between the reference signal FREF10 and the internal signal A occurs, and the UP signal 31 corresponds to this period (i.e., a period from when the reference signal FREF10 has risen until the comparison signal FVCO20 has risen and then the predetermined delay time D lapses). As shown in FIGS. 9B and 10B, in the case of the phase lead, an overlapping period of Hi level between the comparison signal FVCO20 and the internal signal B occurs, and the DN signal 41 corresponds to this period (i.e., a period from when the comparison signal FVCO20 has risen until the reference signal FREF10 has risen and then the predetermined delay time D lapses). As shown in FIGS. 9C and 10C, in the case of the phase match, an overlapping period of Hi level between the reference signal FREF10 and the internal signal A, and an overlapping period of Hi level between the comparison signal FVCO20 and the internal signal B, occur simultaneously, and the UP signal 31 and the DN signal 41 are output at the same timing.

In the conventional configuration, in the case of the phase match, the UP signal 30 and the DN signal 40 are output simultaneously because of the operation of the delay element 3 for preventing a dead band in the frequency/phase comparator. For this reason, if there is a difference between a charging current and a discharging current of a charge pump current during a period for which the UP signal 30 and the DN signal 40 are output simultaneously, a steady phase error for compensating this occurs, and the UP current 30 or the DN current 40 flowing during the resulting phase error period causes a voltage fluctuation in the loop filter. This causes a regular fluctuation in the comparison signal FVCO20 output from the voltage controlled oscillator 800, thereby resulting in a spurious (reference leak) in frequencies with which the phases are to be compared.

On the other hand, in the phase comparison circuit 200 having the above configuration, at a time point when almost no phase difference substantially remains, the UP signal 31 or the DN signal 41 which was not output before that point of time starts to be output, but no signal pulse appear as will be described later. When the UP signal 31 or the DN signal 41 becomes a pulse duration which is not less than a dead band x, both of the UP signal 31 and the DN signal 41, instead of either one of the UP signal 31 and the DN signal 41, appear as signal pulses. As a result, a difference in pulse duration between the UP signal 31 and the DN signal 41, becomes a phase error amount. This allows both of the UP signal 31 and the DN signal 41 to compensate a difference in the charge pump current during the period for which the UP signal 31 and the DN 41 signal are output simultaneously, if the difference exists while preventing the dead band from being generated effectively. As a result, a period for which the steady phase error is generated can be reduced to a half of the period for which the steady phase error is generated in the conventional configuration or technique.

As should be appreciated from the above, in the case of a lock state where there is no substantial phase difference, a difference in pulse duration between the UP signal 31 and the DN signal 41 is a phase error amount, and therefore, it is possible to reduce a phase error amount irrespective of minimum pulse durations of the UP signal 31 and the DN signal 41. Therefore, particularly in the case where there is no substantial phase difference, a steady phase difference can be reduced and the lock state can be stabilized, thus effectively suppressing the spurious.

Furthermore, since the phase comparator circuit 200 is constituted by the elements fewer than those in a comparator circuit of an edge detection type including a latch, a thermal noise can be suppressed.

Hereinafter, a case where the phase difference is small will be described in detail.

As shown in FIG. 10A, in the case of the phase lag, as the UP signal 31, a signal having a pulse duration of a time (α+D) which is a sum of the phase difference (α) and the delay period (D) of the first delay unit 5 is output. In contrast, the DN signal 41 is defined as a signal having a pulse duration of a time (D−α) which is obtained by subtracting the phase difference (α) from the delay period (D) of the second delay unit 7. As shown in FIG. 10A, this time (D−α) is shorter than the dead band (x), and therefore the pulse of the DN signal 41 is not output. As a result, only the UP signal 31 is output. The delay time of the first delay unit 5 and the delay time of the second delay unit 7 are set to a value (x+δ) which is larger than the dead band (x) by a very small value (δ). Therefore, the time (D−α) of the DN signal 41 is expressed as the following formula (1):

D−α=(x+δ)−α (1)

>x(α<δ)

≦x(α≧δ)

Therefore, the pulse of the DN signal 41 is not output in cases (α≧δ) except for a case where the phase difference is extremely small (α<δ). On the other hand, in a case where the phase is extremely small (α<δ), the DN signal 41 is larger than the dead band (x), and its pulse is output.

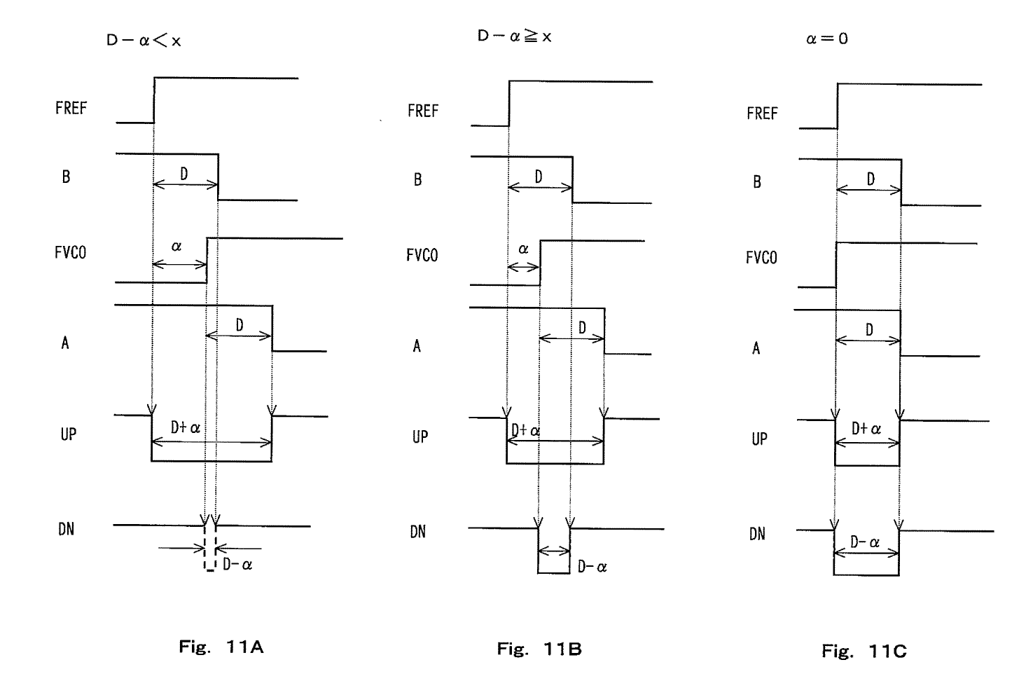

FIGS. 11A to 11C are views showing output waveforms of signals in a case where there is a phase lag occurs and its phase difference is small in the phase comparator circuit 200 of FIG. 7. FIG. 11A is a waveform diagram of outputs in a case where the phase difference α is smaller than the delay time D and the time (D−α) is smaller than the dead band (x). FIG. 11B is a waveform diagram of outputs in a case where the phase difference α is smaller than the delay time D and the time (D−α) is not smaller than the dead band (x) (phase difference α is smaller than that in the case of FIG. 11A). FIG. 11C is a waveform diagram of outputs in a case where the phase difference α is 0. As shown in FIG. 11A, when the phase difference α is smaller than the delay time D, the UP signal 31 (α+D period) is output and the DN signal 41 (D−α period) is defined. If the time (D−α) is smaller than the dead band (x), the DN signal 41 is not actually output (this state is the same as that in the example of FIG. 10A). However, when the phase difference α decreases and the time (D−α) becomes the dead band (x) or more, the DN signal 41 is output in addition to the UP signal 31, as shown in FIG. 11B. After the time (D−α) becomes the dead band (x) or more, the pulse duration of the UP signal 31 decreases but the pulse duration of the DN signal 41 increases as the phase difference α decreases. As shown in FIG. 11C, when the phase difference α reaches 0, the UP signal 31 and the DN signal 41 are output with an equal pulse duration which is equal to the delay period D.

As described above, in a case where the phase difference α is much smaller than the delay time D, the phase error signal is output according to a decrease amount of the pulse duration of the UP signal 31 and an increase amount of the pulse width of the DN signal 41, and therefore a phase comparison gain doubles. Because of this, a current of the charge pump can be reduced to a half This can reduce a difference in a current mismatch.

Likewise, as shown in FIG. 10B, in the case of the phase lead, as the DN signal 41, a signal having a pulse of a time (β+D) which is a sum of a phase difference (β) and the delay time (D) of the second delay unit 7, is output. On the other hand, the UP signal 31 is defined as a signal having a pulse duration of a time (D−β) which is obtained by subtracting the phase difference (β) from the delay time (D) of the first delay unit 5. In the example of FIG. 10B, this time (D−β) is shorter than the dead band (x), and therefore the pulse of the UP signal 31 is not output. Therefore, only the DN signal 41 is output. The delay time of the first delay unit 5 and the delay time of the second delay unit 7 are set to a value which is larger than the dead band (x) by a very small value (δ). Thus, the time (D−β) of the UP signal 31 is expressed as the following formula (2):

D−β=(x+δ)−β (2)

>x(β<δ)

≦x(β≧δ)

Therefore, the pulse of the UP signal 31 is not output in cases ((β≧δ) except for a case where the phase difference is extremely small (β<δ). On the other hand, in a case where the phase is extremely small (β<δ), the UP signal 31 is larger than the dead band (x), and its pulse is output.

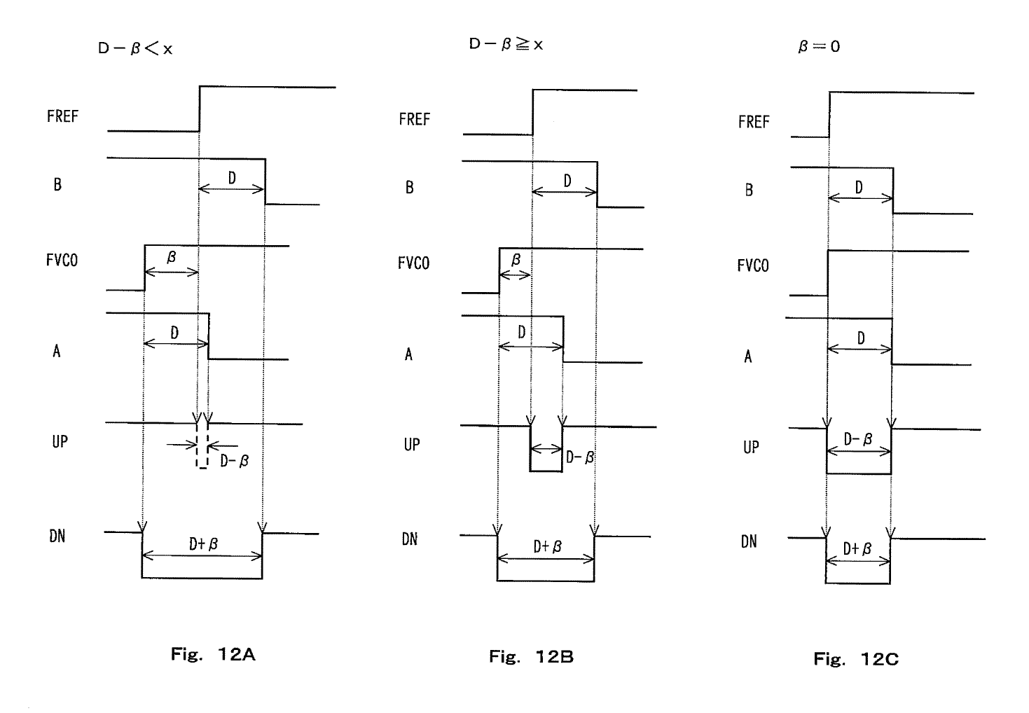

FIGS. 12A to 12C are views showing output waveforms of signals in a case where a phase lead occurs and its phase difference is small in the phase comparator circuit 200 of FIG. 7. FIG. 12A is a waveform diagram of outputs in a case where the phase difference β is smaller than the delay time D and the time (D−β) is smaller than the dead band (x). FIG. 12B is a waveform diagram of outputs in a case where the phase difference β is smaller than the delay time D and the time (D−α) is not smaller than the dead band (x) (phase difference β is smaller than that in the case of FIG. 12A). FIG. 12C is a waveform diagram of outputs in a case where the phase difference β is 0. As shown in FIG. 12A, when the phase difference β is smaller than the delay time D, the DN signal 41 (β+D period) is output and the UP signal 31 (D−β period) is defined. If this time (D−β) is smaller than the dead band (x), the UP signal 31 is not actually output (this state is the same as that in the example of FIG. 10B). However, when the phase difference β decreases and the time (D−β) becomes the dead band (x) or more, the UP signal 31 is output in addition to the DN signal 41 as shown in FIG. 12B. After the time (D−β) becomes the dead band (x) or more, the pulse duration of the DN signal 41 decreases but the pulse duration of the UP signal 31 increases as the phase difference β decreases. As shown in FIG. 12C, when the phase difference β reaches 0, the UP signal 31 and the DN signal 41 are output with an equal pulse duration which is equal to the delay period D.

As described above, in a case where the phase difference β is much smaller than the delay time D, the phase error signal is output according to a decrease amount of the pulse duration of the DN signal 41 and an increase amount of the pulse width of the UP signal 31, and therefore a phase comparison gain doubles. Because of this, a current of the charge pump can be reduced to a half. This can reduce a difference in a current mismatch.

As described above, the delay time of the first delay unit 5 is equal to the delay time of the second delay unit 7, and each delay time is set to the delay time (D=X+δ) which slightly exceeds the dead band (x). Thus, in the case of the phase match, as shown in FIG. 10C, the UP signal 31 and the DN signal 41 having a pulse duration equal to the delay time D are output simultaneously. In a case where the time (D−α) or the time (D−β) are longer than the dead band (x) (i.e., the phase difference α or β is smaller than the very small value (δ)), the UP signal 31 and the DN signal 41 are generated together. By setting the very small value (δ) to a value closest to 0 (by setting a value of the delay time D substantially equal to a value of the dead band x), occasions in which the UP signal 31 and the DN signal 41 are generated together can be lessened.

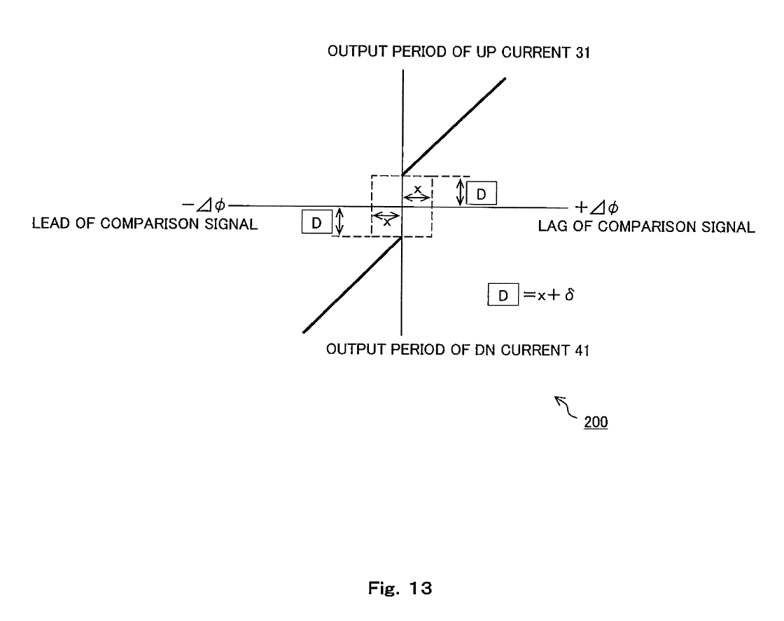

FIG. 13 is a view showing a relationship between a phase difference between the reference signal FREF10 and the comparison signal FVCO20 in the phase comparator circuit 200 of FIG. 7, and an output period of a charge pump current (UP current) based on the UP signal 31 and an output period of a charge pump current (DN current) based on the DN signal 41.

As shown in FIG. 13, by setting the very small value (δ) in the delay time (D) to a minimum value, occasions in which the UP signal 31 and the DN signal 41 are generated together do not substantially occur. Therefore, even when a mismatch (difference in period) occurs between the charging current UP 31 and the discharging current DN41 which are output simultaneously in a state of the phase match, a charge current for compensating such a difference is not output continuously. This makes it possible to prevent the phase difference from being generated steadily. Therefore, in accordance with the configuration of Embodiment 1, since it is possible to suppress a voltage fluctuation in the loop filter which occurs every time the phases are compared, the spurious or jitter can be reduced. As a result, current values of the charge pump current (UP current and DN current) can be reduced without degrading the characteristic.

In accordance with the PLL circuit of this embodiment, if it is detected based on the lock detection signal PLLLOCK70, that the phase difference between the reference signal FREF10 and the comparison signal FVCO20 is small and they are close to the lock state, the frequency/phase comparator 500 does not compare the frequencies of the reference signal FREF10 and the comparison signal FVCO20, but compares the phases of the reference signal FREF10 and the comparison signal FVCO20, and outputs the phase error output signals (UP signal and DN signal), while if it is detected based on the lock detection signal PLLLOCK70, that the phase difference between the reference signal FREF10 and the comparison signal FVCO20 is large, the frequency/phase comparator 500 compares the frequencies, and outputs the phase error output signals. Thus, in the frequency/phase comparator 500 for performing switching control using the lock detection signal PLLLOCK70, if it is detected that the phase difference is relatively large based on the lock detection signal PLLLOCK70, the frequency comparator circuit 300 outputs the phase error output signals, thus shortening a time required to reach the lock state in which the comparison signal FVCO20 is locked to the reference signal FREF10. On the other hand, if it is detected that the comparison signal FVCO20 and the reference signal FREF10 are close to the lock state, based on the lock detection signal PLLLOCK70, the phase comparator circuit 200 which is less likely to generate a reference leak output the phase error output signals, thus suppressing a reference leak due to a mismatch in the charge pump current, and reducing a spurious and a noise amount.

### Embodiment 2

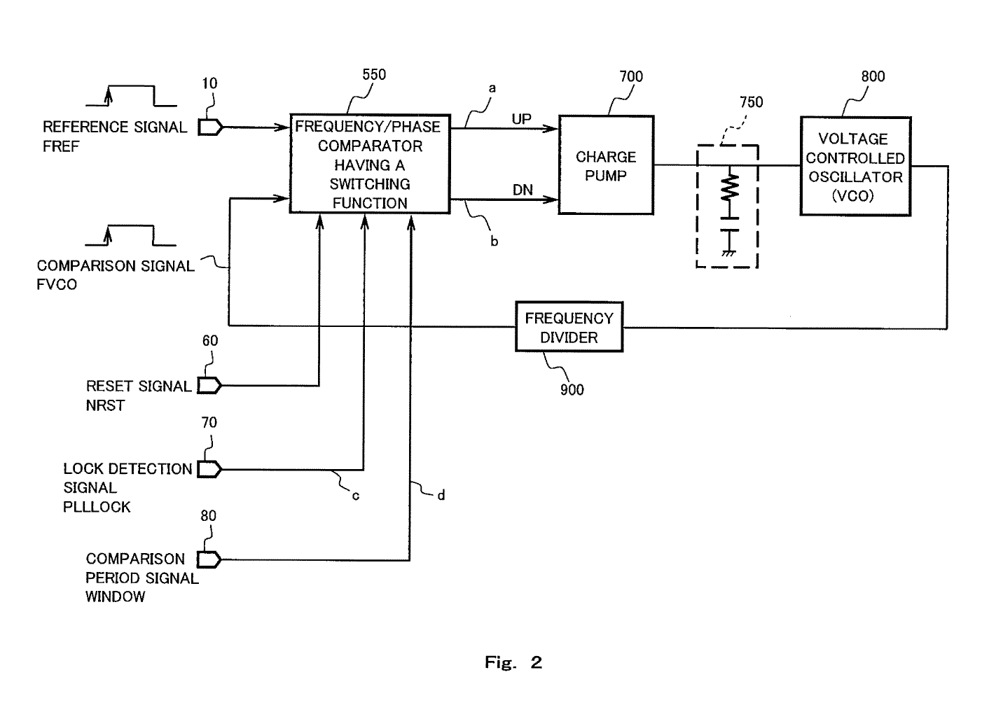

FIG. 2 is a view showing an exemplary configuration of a PLL circuit according to Embodiment 2 of the present invention. In this embodiment, the same components and constituents as those in Embodiment 1 are designated by the same reference symbols and will not be described. In this embodiment, the PLL circuit includes a frequency/phase comparator 550 having a switching unit which is provided with a reset input terminal, instead of the frequency/phase comparator 500 having a switching function of Embodiment 1.

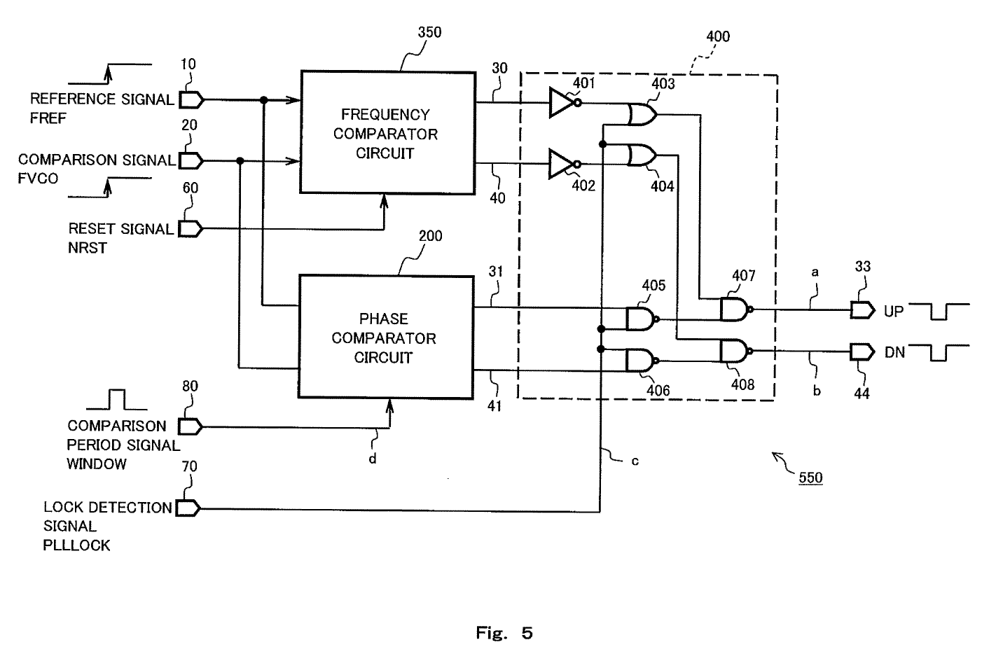

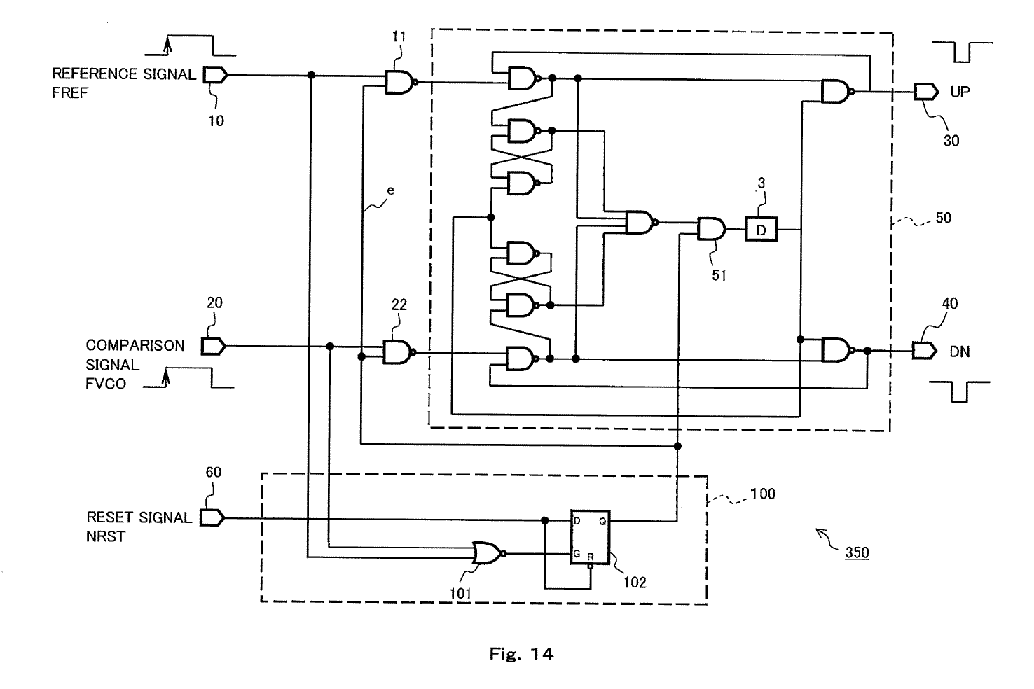

FIG. 5 is a view showing an internal configuration of the frequency/phase comparator 550 having a switching function in the PLL circuit of FIG. 2. Referring to FIG. 5, in this embodiment, the frequency/phase comparator 550 is configured such that a reset signal NRST60 is input to a frequency comparator circuit 350. FIG. 14 shows an internal configuration of the frequency comparator circuit 350 shown in FIG. 5.

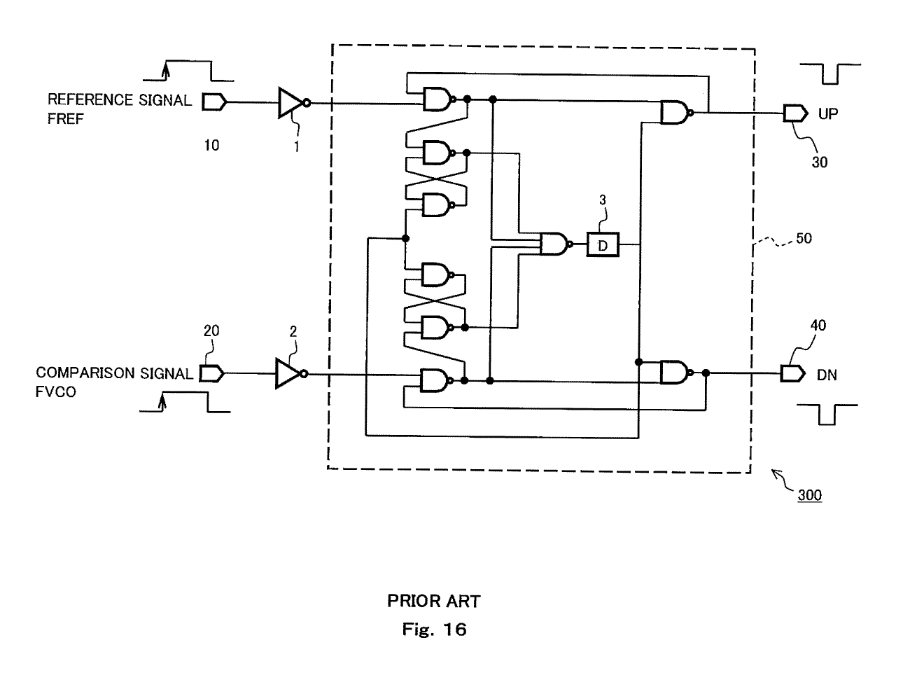

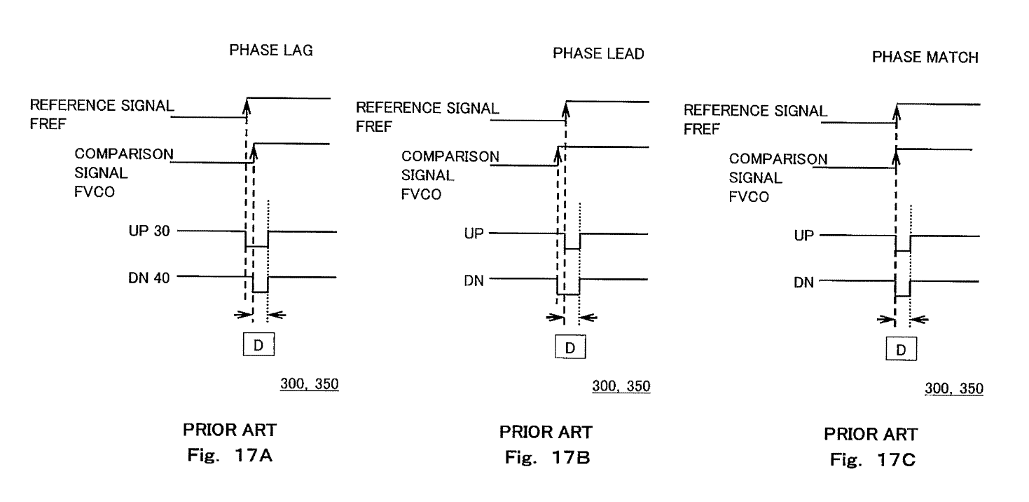

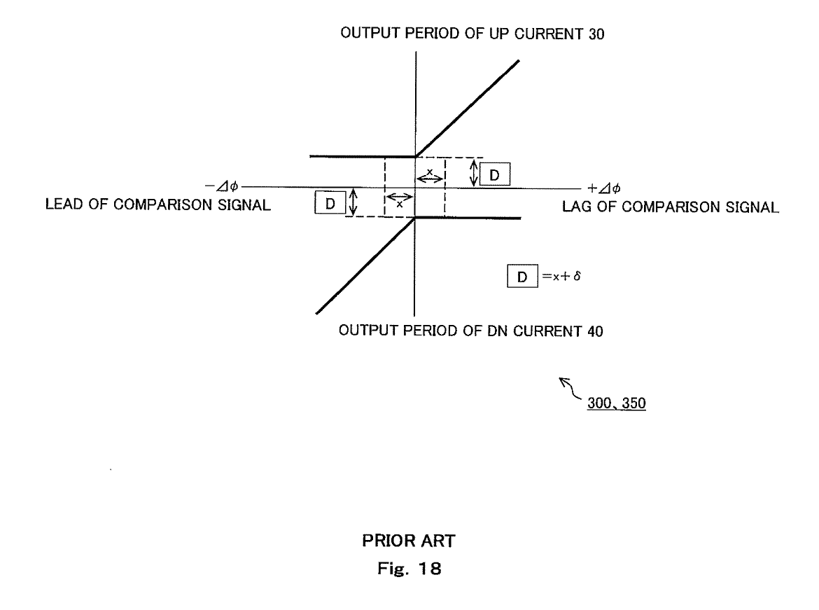

The frequency comparator circuit 350 includes a frequency comparator unit 50 for comparing frequencies of the reference signal FREF10 and the comparison signal FVCO20, a reset signal input processing unit 100 fed with the reset signal NRST60, and a reset state releasing unit. The reset state releasing unit includes a NAND circuit 11 which is fed with the reference signal FREF10 and an output signal of the reset signal input processing unit 100, and outputs a NAND output of these signals to the frequency comparator unit 50, and a NAND circuit 22 which is fed with the comparison signal FVCO20 and an output signal of the reset signal input processing unit 100, and outputs a NAND signal of these signals to the frequency comparator unit 50. As the frequency comparator unit 50, the existing frequency comparator shown in FIG. 16 is used.

The reset signal input processing unit 100 includes a NOR circuit 101 fed with the reference signal FREF10 and the comparison signal FVCO20 and a level latch 102 having a clock input terminal G connected to an output terminal of the NOR circuit 101. The NOR circuit 101 outputs a signal at the second voltage level Hi to the clock input terminal G of the level latch 102 when the reference signal FREF10 and the comparison signal FVCO20 are each at a predetermined voltage level (first voltage level Lo). At this timing, the reset signal NRST60 input to an input terminal D and a reset input terminal R of the level latch 102, is output through an output terminal Q of the level latch 102. The output terminal Q of the level latch 102 is connected to the other input of the NAND circuit 11, the other input of the NAND circuit 22 and the other input of the AND circuit 51, the output of which is connected to an input terminal of the delay unit 3.

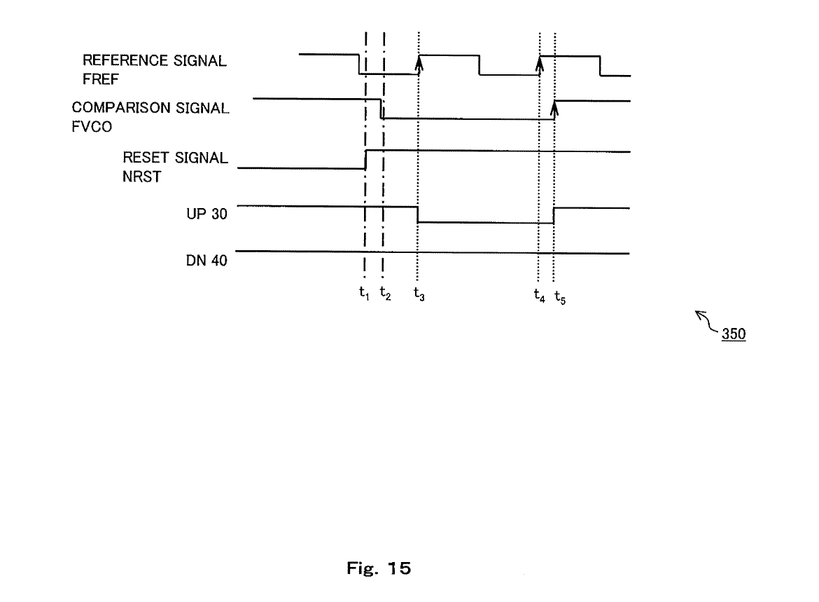

FIG. 15 is a view showing output waveforms of the UP signal 30 and DN signal 40 in the frequency comparator circuit 350 of FIG. 14, just after a power supply is ON. Referring to FIG. 15, before time t₁, a reset state in which the phase error output is not output is formed. Upon the power supply being turned ON or in response to a command of a reset operation, at time t₁, the reset signal NRST60 transitions from the first voltage level Lo at which the reset state continues to the second voltage level Hi at which the reset state is released. If either one of the reference signal FREF10 and the comparison signal FVCO20 is not at the predetermined voltage level (Lo), the reset state of the frequency comparator unit 50 continues. At time t₂ when the reference signal FREF10 and the comparison signal FVCO20 are at low level, an output signal of the level latch 102 transitions from the first voltage level Lo to the second voltage level Hi for the first time, in which state, the NAND circuits 11 and 12, and the AND circuit 51 can output signals at the second voltage level Hi. Therefore, the reset state of the frequency comparator unit 50 is released.

Therefore, at a timing of rising of the reference signal FREF10 at time t₃ following time t₂, the UP signal 30 is output, and at a timing of rising of the comparison signal FVCO20 at time t_{5,} outputting of the UP signal 30 ends. The UP signal 30 advances the phase of the comparison signal FVCO20, thereby allowing the comparison signal FVCO20 to be drawn into a frequency of the reference signal FREF10.

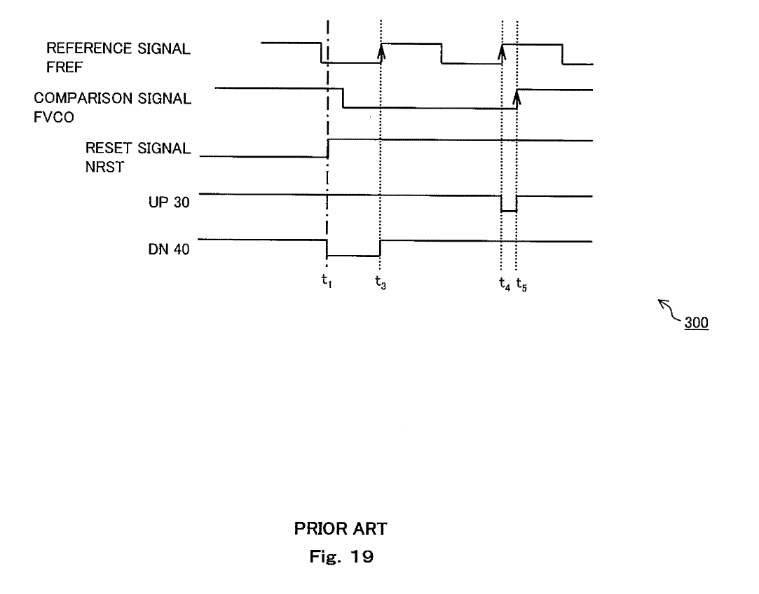

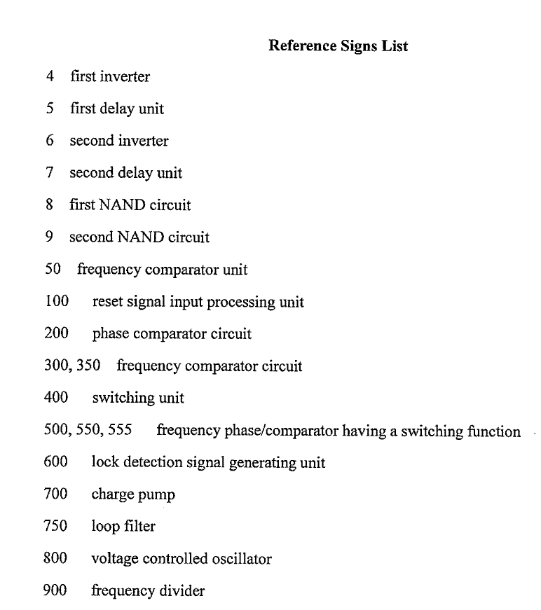

In a comparison example, FIG. 19 shows output waveforms of the UP signal 30 and the DN signal 40 in the conventional frequency/phase comparator 300 (FIG. 16) from which the reset signal input processing unit 100 of the reset signal NRST60 is omitted, just after the power supply is ON. As shown in FIG. 19, in the conventional configuration, the reset signal NRST60 is released at time t₁ like this embodiment. But, since the reset signal NRST60 is released when the comparison signal FVCO20 is at Hi level, the DN signal 40 is output before time t3 when a rising edge of the reference signal FREF10 occurs, i.e., for a period of time from time t₁ to time t₃. Since the phase of the comparison signal FVCO20 is retarded with respect to the phase of the reference signal FREF10, the DN signal 40 is output although the UP signal 30 should be output. This results in an increase a lock time which is a time required to synchronize the phases of the reference signal FREF10 and the comparison signal FVCO20 after the power supply is ON.

As shown in FIG. 19, the UP signal 30 which should be output is output for a period of time from time t₄ to time t₅, but does not cancel the DN signal 40 output for the period of time from time t₁ to time t₃.

On the other hand, as described above, in accordance with Embodiment 2, since rising edges of the reference signal FREF10 and the comparison signal FVCO20 can be detected properly, the lock time can be reduced, and spurious and jitter can be lessened.

### Embodiment 3

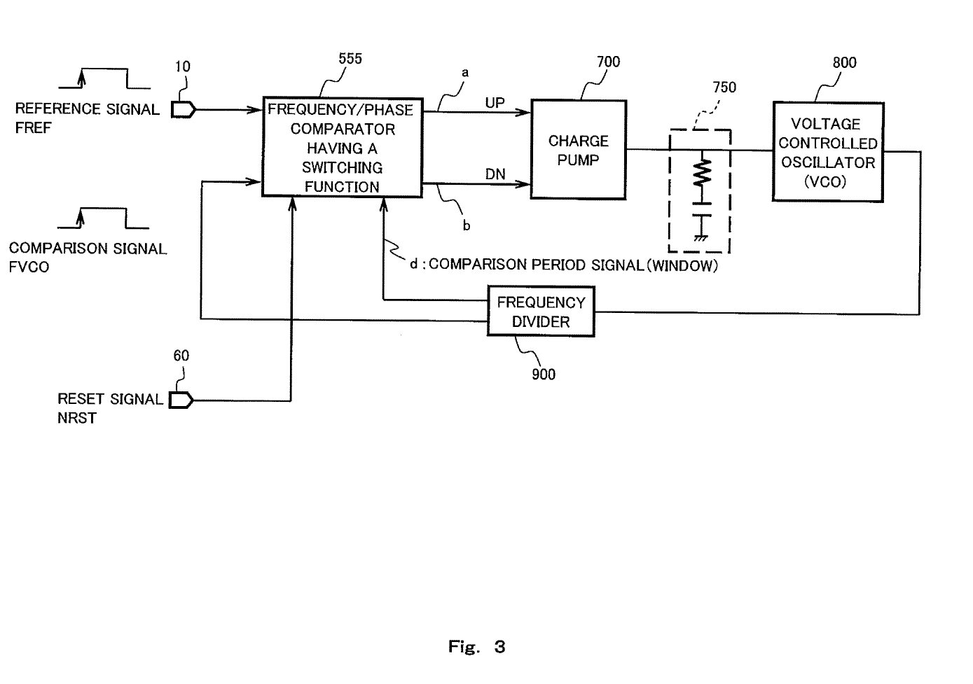

FIG. 3 is a view showing an exemplary configuration of a PLL circuit according to Embodiment 3 of the present invention. In this embodiment, the same components and constituents as those in Embodiment 2 are designated by the same reference symbols and will not be described.

The PLL circuit of Embodiment 3 is different from the PLL circuit of Embodiment 2 in that a frequency/phase comparator 555 having a switching function includes a lock detection signal generating unit 600 for generating the lock detection signal PLLLOCK70, according to the comparison period signal WINDOW80 and the reference signal FREF10.

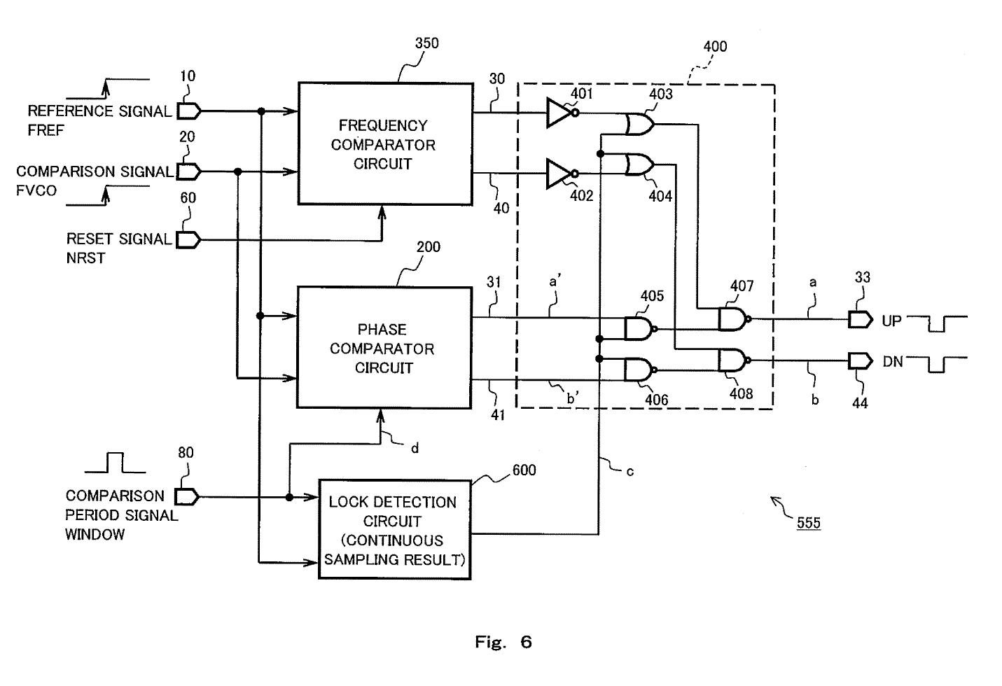

FIG. 6 is a view showing an internal configuration of the frequency/phase comparator 555 having a switching function in the PLL circuit of FIG. 3. Referring to FIG. 6, the lock detection signal generating unit 600 is fed with the comparison period signal WINDOW80 as a data signal and the reference signal FREF10 as a clock signal.

The lock detection signal generating unit 600 generates the lock detection signal PLLLOCK70, when it is detected that the reference signal FREF10 switches to a predetermined voltage level (Hi) predetermined number of times (predetermined number of rising edges) within a comparison period based on the comparison period signal WINDOW80 as shown in FIG. 8. In this way, since the lock detection signal PLLLOCK70 is generated based on the reference signal FREF10 and the comparison period signal WINDOW80, the lock state can be easily detected in a simple circuit.

The PLL circuit of Embodiment 3 can lessen a spurious and a jitter due to an error current mismatch while reducing a lock time (time required to reach a lock state between the reference signal FREF10 and the comparison signal FVCO20), like the PLL circuit of other embodiment.

Thus far, embodiments and modification examples thereof the present invention have been described. The present invention is not limited to them, but can be improved, altered or modified, within a scope of the invention. For example, constituents in the above embodiments and modification examples may be combined as desired.

Although in Embodiment 1 to Embodiment 3, the frequency/phase comparators 500, 550 and 555 are configured such that the phase comparator circuit 200 is selected when the lock detection signal PLLLOCK70 used for switching between the frequency comparator circuit 300 or 350 and the phase comparator circuit 200 becomes the second voltage level Hi, the phase comparator circuit 200 may alternatively be selected when the lock detection signal PLLLOCK70 becomes the first voltage level Lo.

As should be appreciated from above, since the PLL circuit of the present invention can reduce the lock time and make it difficult to generate a steady phase difference caused by compensating an error current mismatch even if the error current mismatch exists, it can suppress a voltage fluctuation in the loop filter which occurs periodically at timings when the phases are compared in the conventional example, and lessen a spurious and a jitter. Therefore, the PLL circuit of the present invention is useful as a synchronous clock generating circuit or the like in a semiconductor integrated circuit.

Numerous modifications and alternative embodiments of the present invention will be apparent to those skilled in the art in view of the foregoing description. Accordingly, the description is to be construed as illustrative only, and is provided for the purpose of teaching those skilled in the art the best mode of carrying out the invention. The details of the structure and/or function may be varied substantially without departing from the spirit of the invention.

What is claimed is:

1. A phase locked loop circuit comprising:
a charge pump fed with a phase error output signal;
a loop filter charged or discharged with an output of the charge pump;
an oscillator, an oscillating frequency of which is controlled in accordance with a voltage of the loop filter; and
a frequency/phase comparator having a switching function which is fed with a reference signal and an output signal of the oscillator and outputs the phase error output signal between the reference signal and a comparison signal based on the output signal of the oscillator;
the frequency/phase comparator having a switching function being configured to, based on a lock detection signal input to the frequency/phase comparator, switch between comparing frequencies of the reference signal and the comparison signal by detecting rising edges of the reference signal and the comparison signal to detect a phase difference between the reference signal and the comparison signal, and comparing phases of the reference signal and the comparison signal by detecting voltage levels of the reference signal and the comparison signal to detect a phase difference between the reference signal and the comparison signal.

2. The phase locked loop circuit according to claim 1, wherein
the frequency/phase comparator having a switching function includes:
a frequency comparator circuit for comparing the frequencies of the reference signal and the comparison signal;
a phase comparator circuit for comparing the phases of the reference signal and the comparison signal;
a switching unit configured to, based on the lock detection signal, switch an operation of the frequency/phase comparator having a switching function to cause the frequency comparator circuit to compare the frequencies or the phase comparator circuit to compare the phases; and
a comparison period signal input terminal fed with a signal (comparison period signal) indicating a period (comparison period) during which the phase comparator circuit is activated to compare the phases;
wherein the phase comparator circuit compares the phases in a state where the comparison period signal is at a predetermined voltage level.

3. The phase locked loop circuit according to claim 1, wherein
the frequency/phase comparator having a switching function includes:
a frequency comparator circuit for comparing the frequencies of the reference signal and the comparison signal;
a reset signal input terminal through which a reset signal is input to the frequency comparator circuit; and
a reset state releasing unit configured to limit the frequency comparator circuit such that a reset state is released, when the reference signal and the comparison signal reach a predetermined voltage level after the reset signal is input to the frequency comparator circuit, in the reset state where the phase error output signal is not output.

4. The phase locked loop circuit according to claim 1, further comprising:
a frequency divider for dividing a frequency of the output signal of the oscillator; wherein
a phase difference between the reference signal and an output signal of the frequency divider is the phase error output signal.

5. The phase locked loop circuit according to claim 2, wherein
the frequency/phase comparator having a switching function includes:
a lock detection signal generating unit fed with the comparison period signal and the reference signal and configured to generate the lock detection signal based on the comparison period signal and the reference signal.

6. The phase locked loop circuit according to claim 2, wherein
the frequency/phase comparator having a switching function limits the comparison period during which the phase comparator circuit outputs the phase error output signal in accordance with the comparison period signal input to the phase comparator circuit.

7. The phase locked loop circuit according to claim 1, wherein
the phase comparator circuit in the frequency/phase comparator having a switching function detects and outputs a voltage level of the reference signal and a voltage level of the comparison signal, as the phase error output signal.

8. The phase locked loop circuit according to claim 2, wherein
the phase comparator circuit includes a phase comparison output signal generating circuit which outputs, in the comparison period, an UP signal indicating that a phase of the comparison signal is retarded with respect to a phase of the reference signal during a period for which a voltage level of the reference signal is a predetermined voltage level and a voltage level of a first delay signal generated by delaying an inverted signal of the comparison signal by a predetermined delay time is a predetermined voltage level, and which outputs, in the comparison period, a DN signal indicating that the phase of the comparison signal is advanced with respect to the phase of the reference signal during a period for which a voltage level of the comparison signal is a predetermined voltage level and a voltage level of a second delay signal generated by retarding an inverted signal of the reference signal by a predetermined delay time is a predetermined voltage level.

9. The phase locked loop circuit according to claim 8, wherein
the comparison period signal is a signal that transitions in voltage level to a second voltage level higher than a first voltage level in the comparison period including a time when the comparison signal switches in voltage level from the first voltage level to the second voltage level;
wherein the phase comparison output signal generating circuit includes:
a first inverter for inverting the comparison signal;
a first delay unit for delaying the comparison signal by a predetermined delay time;
a first NAND circuit fed with the first delay signal, the reference signal and the comparison period signal;
a second inverter for inverting the reference signal;
a second delay unit for delaying the reference signal by a predetermined delay time; and
a second NAND circuit fed with the second delay signal, the comparison signal and the comparison period signal.

10. The phase locked loop circuit according to claim 5, wherein
the lock detection signal generating unit generates the lock detection signal when it is detected that the reference signal switches to a predetermined voltage level a predetermined number of times within the comparison period based on the comparison period signal.
